(19) United States
(12) Patent Application Publication
(10) Pub. No.: US 2026/0068222 A1
(43) Pub. Date: Mar. 5, 2026

(54) BACKSIDE CONTACT WITHOUT RX LINER

(71) Applicant: International Business Machines Corporation, Armonk, NY (US)

(72) Inventors: Min Gyu Sung, Latham, NY (US); Tao Li, Slingerlands, NY (US); Ruilong Xie, Niskayuna, NY (US); Nicolas Jean Loubet, GUILDERLAND, NY (US)

(21) Appl. No.: 18/822,604

(22) Filed: Sep. 3, 2024

(51) Int. Cl. H01L 29/417; H01L 29/06; H01L 29/423; H01L 29/66; H01L 29/775; H01L 29/786

(52) U.S. Cl. CPC H10D 30/6729; H10D 62/116; H10D 30/014; H10D 30/43; H10D 30/6735; H10D 30/6757; H10D 62/121

(57) ABSTRACT

A nanosheet semiconductor structure including a placeholder directly beneath a source drain region, a backside contact structure adjacent to the placeholder, and a backside spacer layer surrounding the placeholder and partially surrounding a top portion of the backside contact structure.

### BACKGROUND

The present invention generally relates to semiconductor structures, and more particularly to nanosheet transistor structures having backside contacts without RX liner.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a placeholder directly beneath a source drain region, a backside contact structure adjacent to the placeholder, and a backside spacer layer surrounding the placeholder and partially surrounding a top portion of the backside contact structure.

According to another embodiment of the present invention, a semiconductor structure is provided. The semiconductor structure may include a placeholder directly beneath a source drain region, a backside contact structure adjacent to the placeholder, and a backside spacer layer surrounding the placeholder and directly contacting bottommost surfaces of bottommost nanosheet channels.

According to another embodiment of the present invention, a semiconductor structure is provided. The semiconductor structure may include a placeholder directly beneath a source drain region, a backside contact structure adjacent to the placeholder, and a backside spacer layer surrounding the placeholder, where protruding portions of the backside dielectric are substantially aligned with nanosheet channels.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of the semiconductor structure after flipping the assembly and recessing the substrate according to an exemplary embodiment;

FIGS. 8, 9, and 10 are cross-sectional views of the semiconductor structure after removing and recessing remaining portions of the substrate according to an exemplary embodiment;

FIGS. 11, 12, and 13 are cross-sectional views of the semiconductor structure after removing portions of the isolation liner and inner spacers according to an exemplary embodiment;

FIGS. 14, 15, and 16 are cross-sectional views of the semiconductor structure after removing the isolation fill according to an exemplary embodiment;

FIGS. 17, 18, and 19 are cross-sectional views of the semiconductor structure after forming a backside spacer layer according to an exemplary embodiment;

FIGS. 20, 21, and 22 are cross-sectional views of the semiconductor structure after forming a backside dielectric layer according to an exemplary embodiment;

FIGS. 23, 24, and 25 are cross-sectional views of the semiconductor structure after forming a mask and removing portions of the backside dielectric layer to create backside contact trenches according to an exemplary embodiment;

FIGS. 26, 27, and 28 are cross-sectional views of the semiconductor structure after removing exposed portions of the backside spacer layer according to an exemplary embodiment;

FIGS. 29, 30, and 31 are cross-sectional views of the semiconductor structure after removing the mask and removing exposed portions of the placeholders according to an exemplary embodiment, and

FIGS. 32, 33, and 34 are cross-sectional views of the semiconductor structure after forming backside contact structures and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional backside contact and placeholder fabrication techniques result in a higher risk of undesirable airgaps or voids forming during backside dielectric gap fill as dimensions continue to shrink. The backside contact trenches, specifically those destined for backside gate contact (otherwise RX trenches), now have critical dimensions of 20 nm and smaller (e.g. 12 nm and less) for high density layouts. Furthermore, flowable dielectrics used to avoid the unwanted airgaps/voids cannot be used during backside processing due to the high temperatures required by annealing processing in the back-end-of-line. As a result of the smaller dimensions, available materials, and processing limitations, airgaps/voids may form in RX trenches directly beneath the gate. If such airgaps/voids exist within the backside dielectric there is an increased risk of exposing the gate during backside source drain contact trench patterning. If the gate is exposed, subsequent metal contact fill, intended to form backside source drain contacts, will short to the gate.

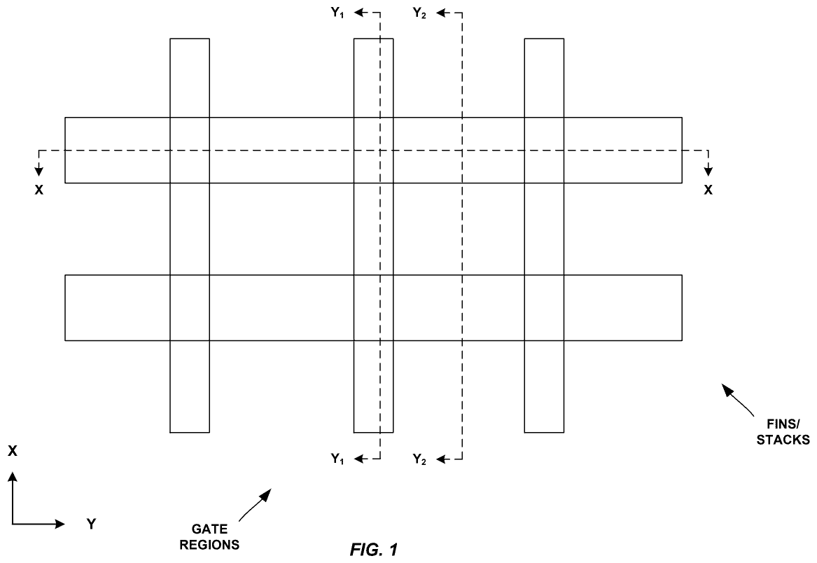

The present invention generally relates to semiconductor structures, and more particularly to nanosheet transistor structures having backside contacts without RX liner. More specifically, the nanosheet transistor structures and associated method disclosed herein enable a novel solution for providing nanosheet transistor structures having backside contacts while decreasing any risks associated with possible short circuits between the backside source drain contacts and the gate. In doing so, the RX liner and STI regions are removed prior to forming any backside contacts. Exemplary embodiments of nanosheet transistor structures having backside contacts without RX liner are described in detail below by referring to the accompanying drawings in FIGS. 1 to 34. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-34 represent cross section views oriented as indicated in FIG. 1.

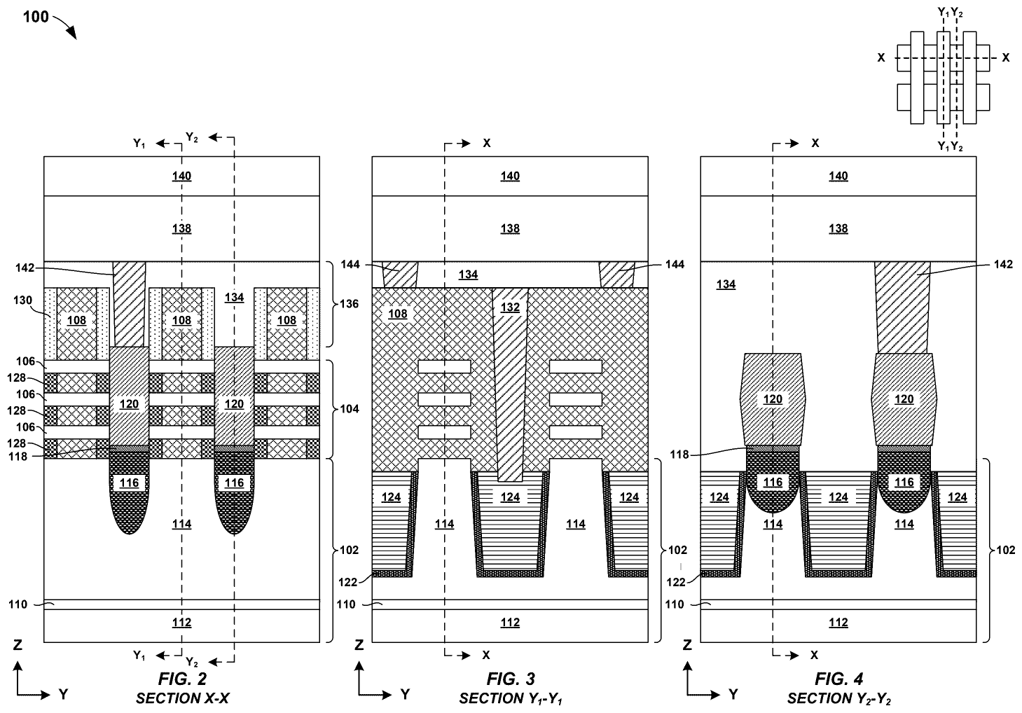

Referring now to FIGS. 2, 3, and 4, a structure 100 is shown during an intermediate step of a method of fabricating a nanosheet transistor structure according to an embodiment of the invention. FIG. 2 depicts a cross-sectional view of the structure 100 taken along line X-X, FIG. 3 depicts a cross-sectional view of the structure 100 taken along line Y₁-Y₁, and FIG. 4 depicts a cross-sectional view of the structure 100 taken along line Y₂-Y₂.

The structure 100 illustrated in FIGS. 2-4 includes an array of nanosheet transistors formed on a substrate 102 in accordance with known techniques. As illustrated, the array of nanosheet transistors includes nanosheet stacks 104. Each nanosheet stack 104 includes a plurality of nanosheet channels 106 surrounded by a single gate 108. For purposes of orientation, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure. As such, thickness of the top semiconductor layer 114, and similarly the position of the etch stop layer 110, approximately denote a relative position of subsequently formed backside features, such as, backside wiring layers or a backside power delivery network.

The structure 100 further includes placeholders 116, buffer layers 118, and source drain regions 120 generally arranged between adjacent nanosheet stacks 104, as illustrated.

The placeholders 116 are formed by filling self-aligned openings in the top semiconductor layer 114 between adjacent nanosheet stacks 104 with a sacrificial material according to known techniques. Specifically, after filling, the sacrificial material is recessed to create the placeholders 116 according to known techniques. In an embodiment, the sacrificial material is silicon germanium or amorphous silicon epitaxially grown from the surfaces of the top semiconductor layer 114. In another embodiment, the sacrificial material is SiC, SiOC deposited using, for example, chemical vapor deposition (CVD) or plasma enhanced CVD (PECVD) and subsequently recessed using, for example, reactive ion etching (RIE). Other suitable deposition and recessing techniques may be used provided they do not induce a physical or chemical change to the nanosheet channels 106.

The buffer layers 118 are formed on top of the placeholders 116 according to known techniques. Specifically, an etch stop material is formed directly on top of the placeholders 116. In an embodiment, the etch stop material can be any silicon-based material suitable to provide needed etch stop properties during backside processing. For example, the buffer layers 118 are designed to allow the subsequent removal of the placeholders 116 selective to the source drain regions 120.

The source drain regions 120 are formed on top of the buffer layers 118 according to known techniques. Specifically, the source drain regions 120 are disposed between adjacent nanosheet stacks 104 in direct contact with exposed ends of the nanosheet channels 106. More specifically, the source drain regions 120 may be epitaxially grown from the exposed ends of the nanosheet channels 106 according to known techniques.

The structure 100 further includes shallow trench isolation regions (hereinafter “STI regions”) which extend partially into the substrate 102 below the array of nanosheet transistors. In general, the STI regions may each include an isolation liner 122 and an isolation fill 124. For example, the isolation liner 122 is SiN, SiON, or SiOCN, and the isolation fill 124 is silicon oxide (SiO) or silicon nitride (SiN).

The structure 100 further includes inner spacers 128, and gate spacers 130, gate cut structures 132, and a dielectric layer 134.

The inner spacers 128 are disposed between alternate channels (106), and laterally separate the gates 108 from the source drain regions 120, as illustrated. The inner spacers 128 provide necessary electrical insulation between the gates 108 and the source drain regions 120.

The gate spacers 130 are added to define the channel length and the source drain regions, and ultimately electrically insulate the gates 108 from subsequently formed structures, such as, for example, source drain contact structures. The gate spacers 130 are critical for electrically insulating the gates 108 from the source drain regions 120 or subsequently formed contact structures. In at least one embodiment, the gate spacers 130 include silicon nitride, silicon boron nitride, silicon carbon nitride, silicon boron carbon nitride, or other known equivalents.

The gate cut structures 132 include liners and gate cut insulators according to an embodiment of the invention. Typically, liners are first formed along opposite sidewalls of gate cut trenches according to known techniques. Specifically, a dielectric liner material is conformally deposited across exposed surfaces of the structure 100 including within the gate cut trenches. After deposition, known directional etching techniques, for example reactive ion etching, may be used to remove excess portions of the dielectric liner material from horizontal surfaces. Doing so will remove portions of the dielectric liner material from bottoms of the gate cut trenches thereby exposing the isolation fill 124 of the STI regions. In an embodiment, the liners are silicon nitride; however, other suitable dielectric liner materials may also be used.

Next, the gate cut insulators are formed on top of the liners and the isolation fill 124 of the STI regions, thereby filling the gate cut trenches according to known techniques. Specifically, a dielectric fill material is blanket deposited across the structure 100 including within the gate cut trenches. After deposition, known chemical mechanical polishing may be used to remove excess portions of the dielectric fill material from top surfaces of the structure 100. After polishing, topmost surfaces of the gate cut insulators, and similarly the gate cut structures 132, are flush, or substantially flush with topmost surfaces of the gates 108. Both the liners and the gate cut insulators may be referred to herein together as the gate cut structures 132.

According to the embodiments disclosed herein, individual gate regions defined by the gate cut structures 132 may include a single nanosheet stack 104 or multiple nanosheet stacks 104 having a common gate 108. Additionally, the different nanosheet stacks 104 separated by the gate cut structures 132 may be N-type, P-type, or any combination thereof. Finally, the gate cut structures 132 can be positioned anywhere according to a desired design, and are not necessarily limited to the positions and configurations depicted and described herein.

Finally, the structure 100 further includes a dielectric layer 134 directly above and surrounding the source drain regions 120. The dielectric layer 134 is composed of any suitable interlayer dielectric material, such as, for example, oxides such as silicon oxide (SiOₓ), nitrides such as silicon nitride (SiₓN_{y}), and/or low-κ materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 134. Using a self-planarizing dielectric material as the dielectric layer 134 can avoid the need to perform a subsequent planarizing step. After formation, top surfaces of the dielectric layer 134 are typically made flush, or substantially flush, with top surfaces of the gates 108 and the gate spacers 130 by chemical mechanical polishing techniques.

The structure 100 further includes a middle-of-line 136, a back-end-of-line 138, a carrier wafer 140.

The middle-of-line 136 includes source drain contacts 142 and gate contacts 144 which may be generally referred to as middle-of-line contacts. The source drain contacts 142 and the gate contacts 144 are formed according to known techniques. The back-end-of-line 138 may include vias and metal lines which may be generally referred to as back-end-of-line interconnects. The vias and the metal lines are formed according to known techniques. Finally, the carrier wafer 140 is secured to a top of the structure 100 according to an embodiment of the invention. The carrier wafer 140 is attached, or removably secured, to the back-end-of-line 138. In general, and not depicted, the carrier wafer 140 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 140 according to known techniques.

Although only a limited number of components, devices, or structures are shown, embodiments of the present invention shall not be limited by any quantity otherwise illustrated or discussed herein.

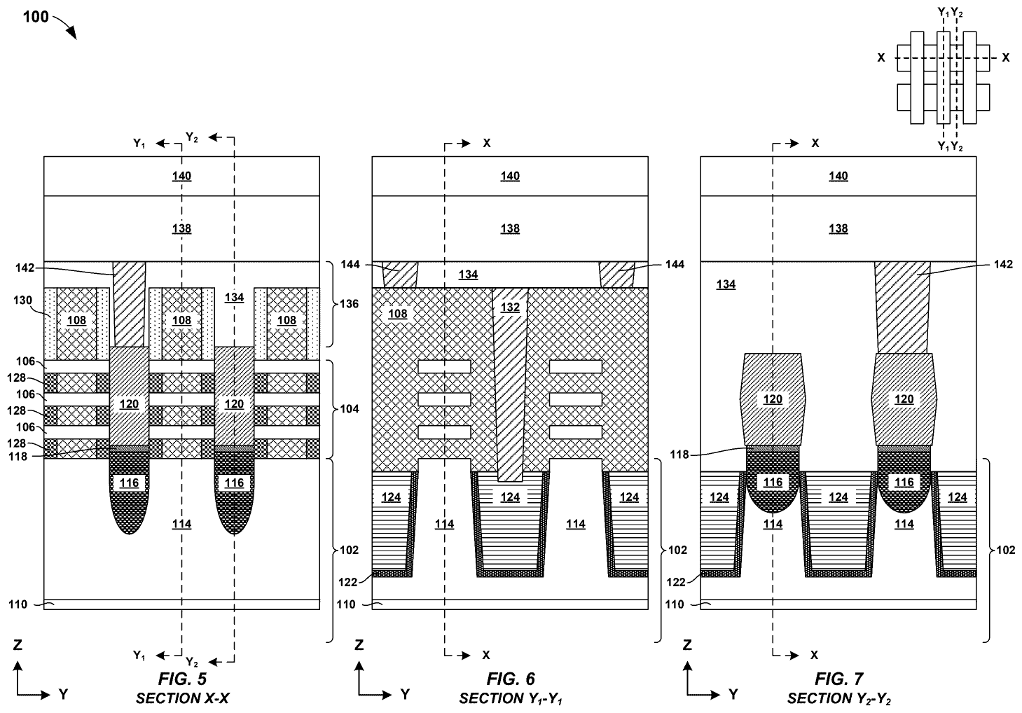

Referring now to FIGS. 5, 6, and 7, the structure 100 is shown after flipping the assembly and recessing the substrate 102 according to an embodiment of the invention. FIG. 5 depicts a cross-sectional view of the structure 100 taken along line X-X, FIG. 6 depicts a cross-sectional view of the structure 100 taken along line Y₁-Y₁, and FIG. 7 depicts a cross-sectional view of the structure 100 taken along line Y₂-Y₂.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

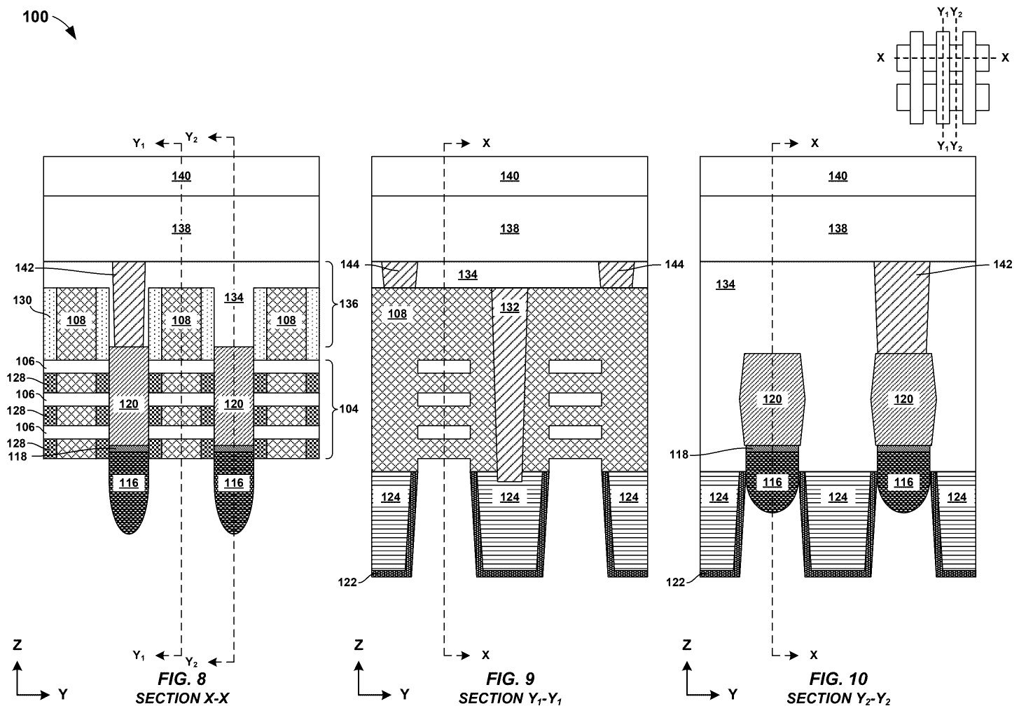

Referring now to FIGS. 8, 9, and 10, the structure 100 is shown after removing and recessing remaining portions of the substrate 102 according to an embodiment of the invention. FIG. 8 depicts a cross-sectional view of the structure 100 taken along line X-X, FIG. 9 depicts a cross-sectional view of the structure 100 taken along line Y₁-Y₁, and FIG. 10 depicts a cross-sectional view of the structure 100 taken along line Y₂-Y₂.

First, the etch stop layer 110 is selectively removed and the top semiconductor layer 114 is recessed according to known techniques. Specifically, the etch stop layer 110 is removed selective to the top semiconductor layer 114 and the top semiconductor layer 114 is removed selective to the placeholders 116, the gates 108, and the STI regions, as illustrated. Despite not being shown, some erosion of the placeholders 116 is anticipated to be an unintended consequence resulting from selectively removing the top semiconductor layer 114.

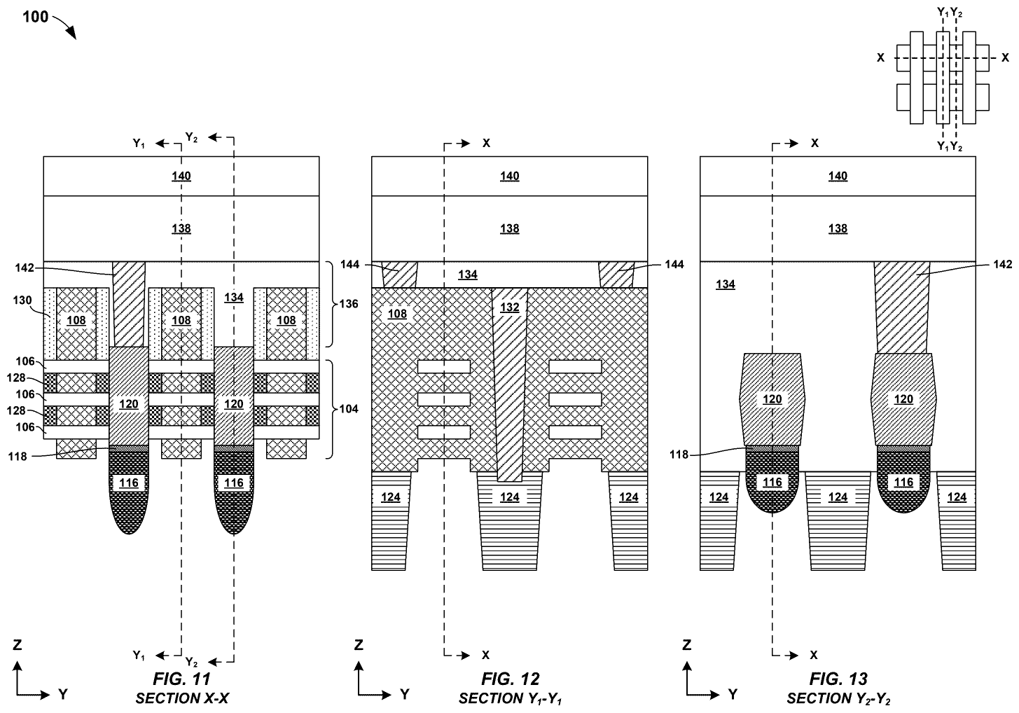

Referring now to FIGS. 11, 12, and 13, the structure 100 is shown after removing portions of the isolation liner 122 and inner spacers 128 according to an embodiment of the invention. FIG. 11 depicts a cross-sectional view of the structure 100 taken along line X-X, FIG. 12 depicts a cross-sectional view of the structure 100 taken along line Y₁-Y₁, and FIG. 13 depicts a cross-sectional view of the structure 100 taken along line Y₂-Y₂.

Exposed portions of the isolation liner 122 and the inner spacers 128 are selectively removed according to known techniques. Specifically, exposed portions of the isolation liner 122 and the inner spacers 128 are removed using known etching techniques suitable to remove nitrides, for example silicon nitride, selective to the bottommost nanosheet channels 106, the gates 108, the buffer layers 118, the placeholders 116, the isolation fill 124, and the dielectric layer 134, as illustrated. In an embodiment, the exposed portions of the isolation liner 122 and the inner spacers 128 are removed using an anisotropic etch such as, for example, reactive ion etching. After removing the exposed portions of the isolation liner 122 and the inner spacers 128, portions of the placeholders 116, the gates 108, and bottommost nanosheet channels 106 become exposed, as illustrated.

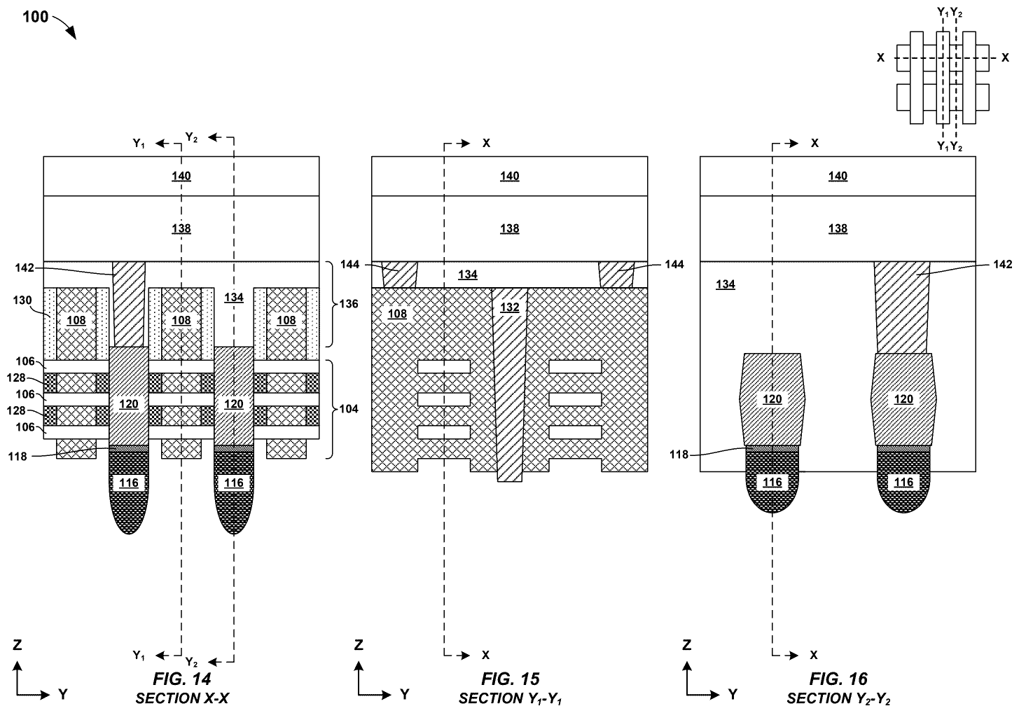

Referring now to FIGS. 14, 15, and 16, the structure 100 is shown after removing the isolation fill 124 according to an embodiment of the invention. FIG. 14 depicts a cross-sectional view of the structure 100 taken along line X-X, FIG. 15 depicts a cross-sectional view of the structure 100 taken along line Y₁-Y₁, and FIG. 16 depicts a cross-sectional view of the structure 100 taken along line Y₂-Y₂.

Exposed portions of the isolation fill 124 are selectively removed according to known techniques. Specifically, exposed portions of the isolation fill 124 are removed using known etching techniques suitable to remove oxides, for example silicon oxide, selective to the bottommost nanosheet channels 106, the gates 108, the buffer layers 118, the placeholders 116, the dielectric layer 134, and the gate cut structures 132, as illustrated. In an embodiment, the exposed portions of the isolation fill 124 are removed using an anisotropic etch such as, for example, reactive ion etching.

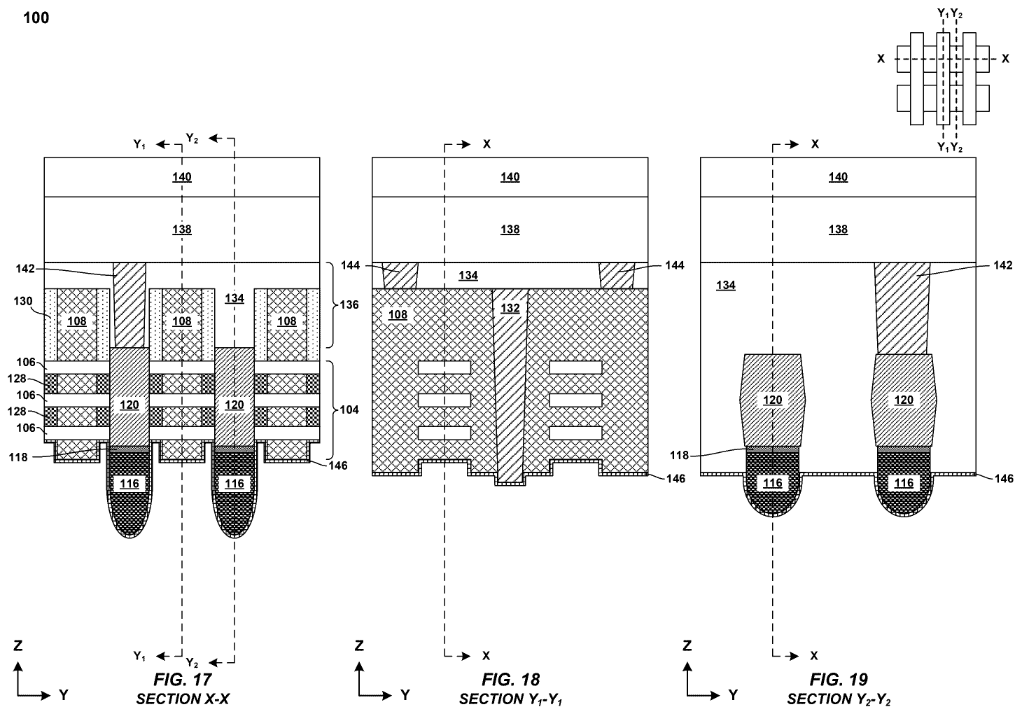

Referring now to FIGS. 17, 18, and 19, the structure 100 is shown after forming a backside spacer layer 146 according to an embodiment of the invention. FIG. 17 depicts a cross-sectional view of the structure 100 taken along line X-X, FIG. 18 depicts a cross-sectional view of the structure 100 taken along line Y₁-Y₁, and FIG. 19 depicts a cross-sectional view of the structure 100 taken along line Y₂-Y₂.

First, the backside spacer layer 146 is formed across the backside of the structure 100 according to known techniques. Specifically, a liner material is conformally deposited across exposed surfaces on the backside of the structure 100 including directly on exposed surfaces of the bottommost nanosheet channels 106, the gates 108, the buffer layers 118, the placeholders 116, the dielectric layer 134, and the gate cut insulators 132, as illustrated. Further, according to an embodiment, the backside spacer layer 146 surrounds sides and a bottom of the placeholders 116.

In some embodiments, for example, the backside spacer layer 146 may be composed of other low-k materials, such as, for example, SiN, SiBCN, SiOCN, SiOC, or other combinations thereof. According to embodiments of the present invention, the backside spacer layer 146 provide etch selectivity during backside processing. More specifically, the backside spacer layer 146 must be made from a material which may be removed selective to the placeholders 116, as described below.

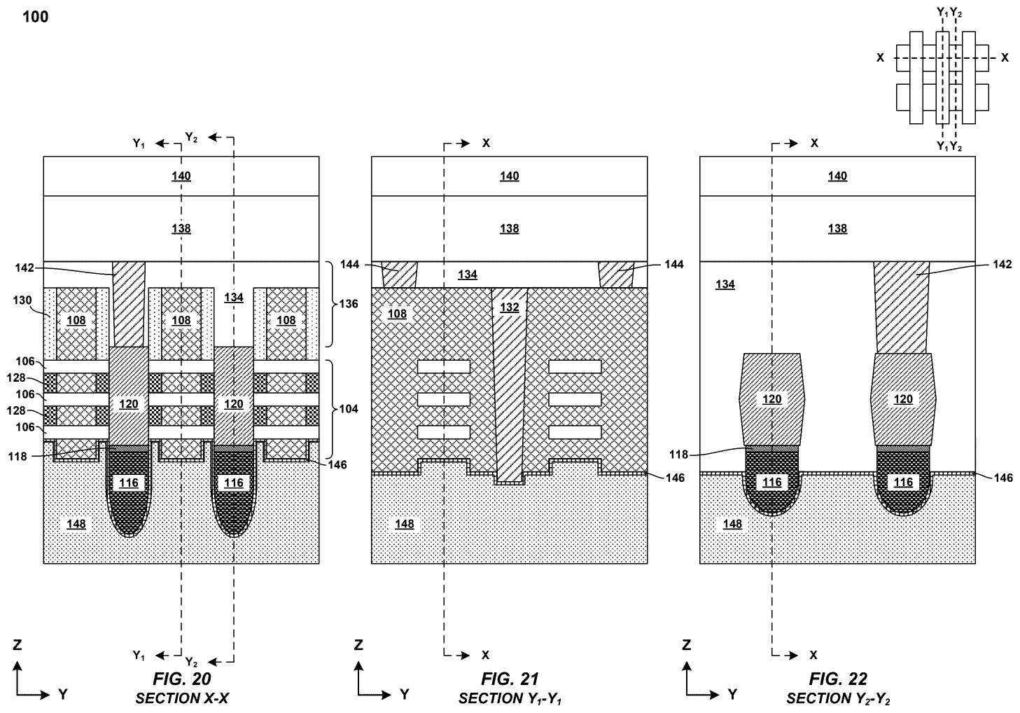

Referring now to FIGS. 20, 21, and 22, the structure 100 is shown after forming a backside dielectric layer 148 according to an embodiment of the invention. FIG. 20 depicts a cross-sectional view of the structure 100 taken along line X-X, FIG. 21 depicts a cross-sectional view of the structure 100 taken along line Y₁-Y₁, and FIG. 22 depicts a cross-sectional view of the structure 100 taken along line Y₂-Y₂.

The backside dielectric layer 148 is deposited according to known techniques. Specifically, a backside dielectric material is blanket deposited across the structure 100. The backside dielectric layer 148 completely covers remaining the backside spacer layer 146 and underlying structures, as illustrated. According to disclosed embodiments, the backside spacer layer 146 conformally contacts a top surface of the backside dielectric layer 148, and physically separates the backside dielectric layer 148 from the gate 108, as illustrated. Further, because of the backside topography, the backside dielectric layer 148 will have vertical pillars which are substantially aligned with inner spacers 128. The vertical pillars essentially take the space of the inner spacers 128 previously removed.

After deposition, known chemical mechanical polishing may be used to remove excess portions of the backside dielectric material from bottom surfaces of the structure 100.

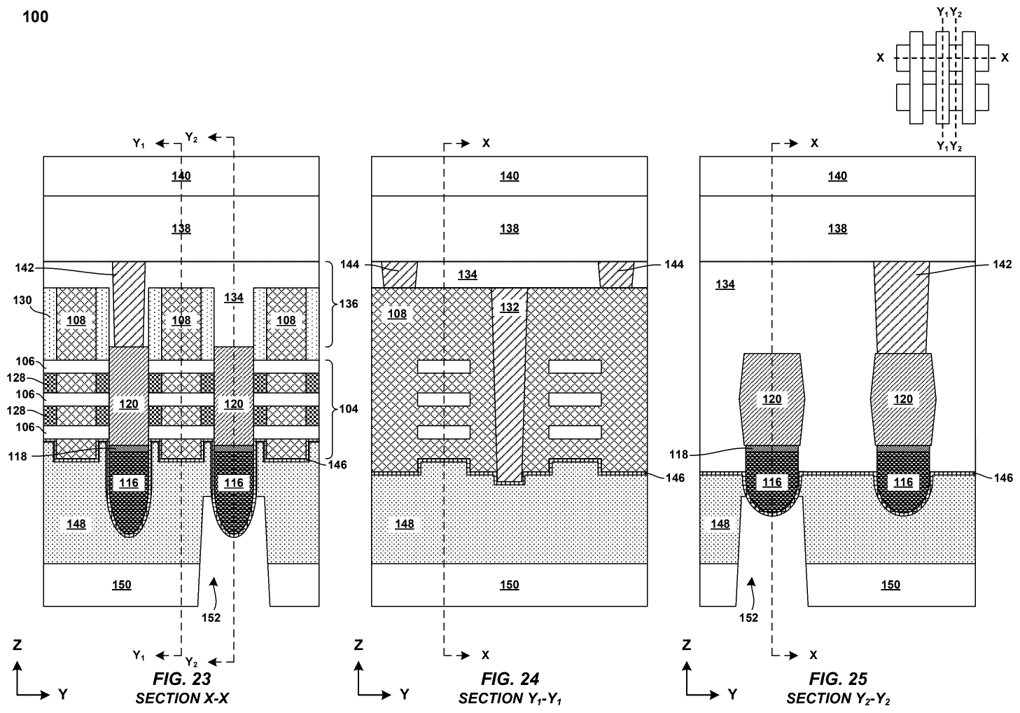

Referring now to FIGS. 23, 24, and 25, the structure 100 is shown after forming a mask 150 and removing portions of the backside dielectric layer 148 to create backside contact trenches 152 according to an embodiment of the invention. FIG. 23 depicts a cross-sectional view of the structure 100 taken along line X-X, FIG. 24 depicts a cross-sectional view of the structure 100 taken along line Y₁-Y₁, and FIG. 25 depicts a cross-sectional view of the structure 100 taken along line Y₂-Y₂.

First, the mask 150 is deposited and subsequently patterned to expose certain portions of the structure 100 according to known techniques. The mask 150 can be an organic planarization layer (OPL) or a layer of material that is capable of being planarized or etched by known techniques. In an embodiment, for example, the mask 150 can be an amorphous carbon layer able to withstand subsequent processing temperatures. The mask 150 can preferably have a thickness sufficient to cover existing structures. After depositing the mask 150, a dry etching technique is applied to pattern or recess the mask 150 according to known techniques. The mask 150 is patterned consistent with a size and a location of subsequently formed backside contacts. For example, after patterning the mask 150, portions of the structure 100 in contact regions are exposed.

Next, exposed portions of the backside dielectric layer 148 are removed according to known techniques. Specifically, exposed portions of the backside dielectric layer 148 are removed using known etching techniques suitable to remove dielectric materials selective to the mask 150 and the backside spacer layer 146. In an embodiment, the exposed portions of the backside dielectric layer 148 are removed using an anisotropic etch such as, for example, reactive ion etching. After removing the exposed portions of the backside dielectric layer 148, portions of the backside spacer layer 146 are exposed at tops of the backside contact trenches 152, as illustrated.

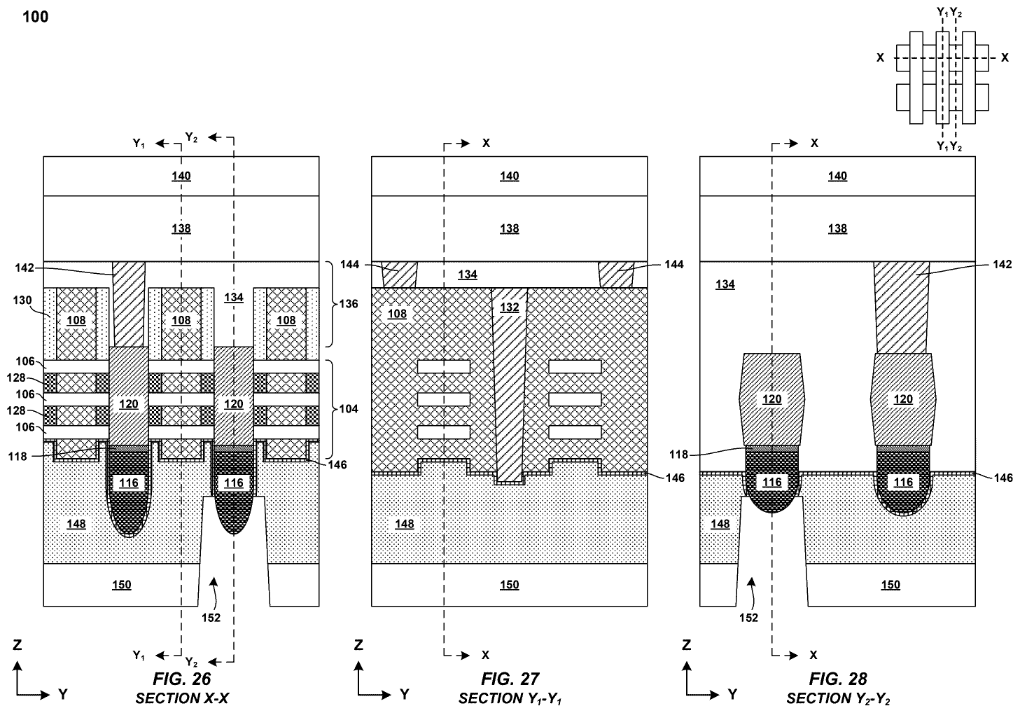

Referring now to FIGS. 26, 27, and 28, the structure 100 is shown after removing exposed portions of the backside spacer layer 146 according to an embodiment of the invention. FIG. 26 depicts a cross-sectional view of the structure 100 taken along line X-X, FIG. 27 depicts a cross-sectional view of the structure 100 taken along line Y₁-Y₁, and FIG. 28 depicts a cross-sectional view of the structure 100 taken along line Y₂-Y₂.

Exposed portions of the backside spacer layer 146 are selectively removed according to known techniques. Specifically, exposed portions of the backside spacer layer 146 are removed using known etching techniques suitable to remove silicon-based materials selective to the mask 150 and the placeholders 116. In an embodiment, the exposed portions of the backside spacer layer 146 are removed using an anisotropic etch such as, for example, reactive ion etching. After removing the exposed portions of the backside spacer layer 146, bottom portions of the placeholders 116 are exposed, as illustrated.

In all cases, at least some portions of the backside spacer layer 146 must remain in non-contact regions of the structure 100. Said differently, the backside spacer layer 146 shall only be removed in contact regions of the structure 100, as illustrated. For example, the portions of the backside spacer layer 146 remaining in the non-contact regions of the structure 100 will serve as a protective layer during subsequent processing.

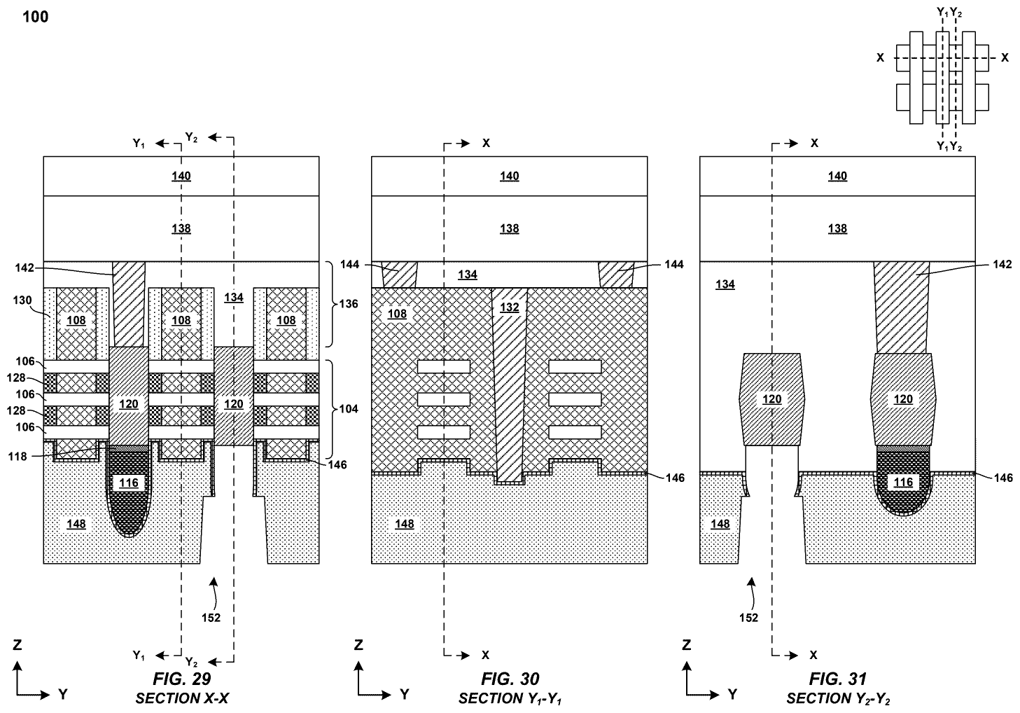

Referring now to FIGS. 29, 30, and 31, the structure 100 is shown after removing the mask 150 and removing exposed portions of the placeholders 116 according to an embodiment of the invention. FIG. 29 depicts a cross-sectional view of the structure 100 taken along line X-X, FIG. 30 depicts a cross-sectional view of the structure 100 taken along line Y₁-Y₁, and FIG. 31 depicts a cross-sectional view of the structure 100 taken along line Y₂-Y₂.

First, the mask 150 is removed according to known techniques. Next, the exposed placeholders 116 are removed according to known techniques. Specifically, the placeholders 116 exposed within the backside contact trenches 152 are etched or removed selective to the backside dielectric layer 148, the backside spacer layer 146, and the buffer layer 118. The placeholders 116 can be removed using compatible selective dry etching techniques.

In doing so, the backside contact trenches 152 are further enlarged directly beneath the source drain regions 120 without exposing the source drain regions 120 due to the existence of the buffer layer 118. Finally, exposed buffer layers 118 are subsequently removed selective to the surrounding structures according to known techniques. In some cases, gouging of the source drain regions 120 may occur.

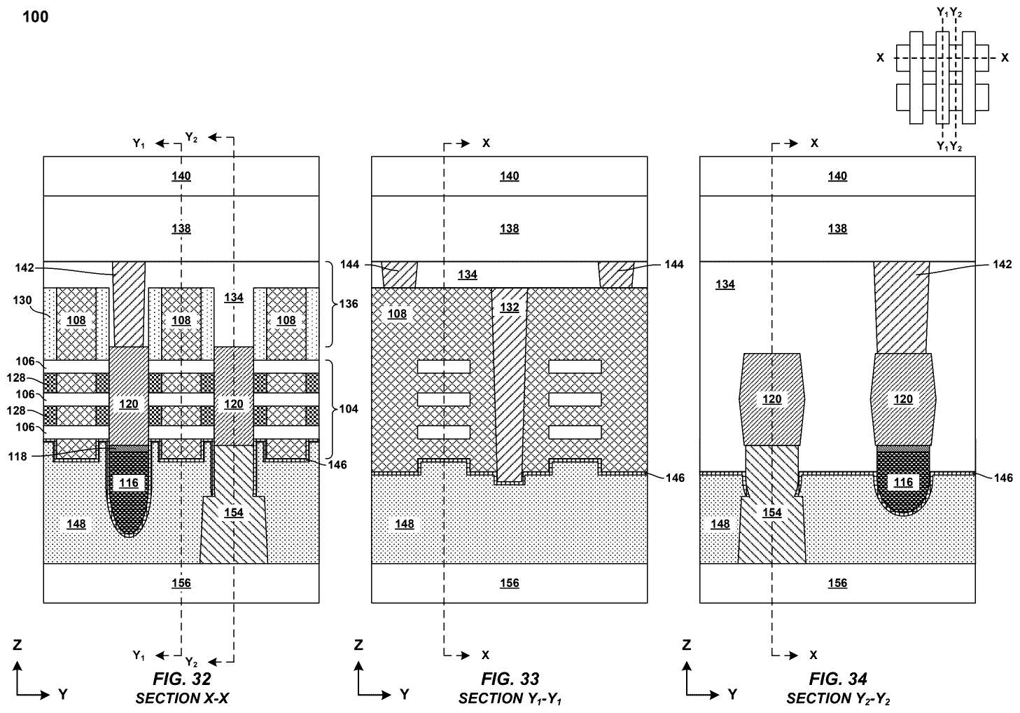

Referring now to FIGS. 32, 33, and 34, the structure 100 is shown after forming backside contact structures 154 and backside wiring layers 156 according to an embodiment of the invention. FIG. 32 depicts a cross-sectional view of the structure 100 taken along line X-X, FIG. 33 depicts a cross-sectional view of the structure 100 taken along line Y₁-Y₁, and FIG. 34 depicts a cross-sectional view of the structure 100 taken along line Y₂-Y₂.

The backside contact trenches 152 are filled with a conductive material to form the backside contact structures 154 according to known techniques. The backside contact structures 154 may include any suitable conductive material, such as, for example, copper, ruthenium, aluminum, tungsten, cobalt, or alloys thereof. In some embodiments, a metal silicide is formed at the bottom of the backside contact trenches prior to filling them with the conductive material.

After, excess conductive material can be polished using known techniques until bottommost surfaces of the backside contact structures 154 are flush, or substantially flush, with bottommost surfaces of the backside dielectric layer 148, as illustrated. After polishing, bottommost surfaces of the backside contact structures 154 are substantially flat. It is noted, the backside contact structures 154 may include, for example, backside source drain contacts, as illustrated, as well as backside gate contacts (not shown). In all cases, a topmost surface of each of the backside contact structures 154 is above a topmost surface of the placeholders 116, as illustrated. Further, the backside contact structures 154 will have a stepped profile in which a top portion will have a different lateral dimension than a bottom portion. More specifically, according to an embodiment, a lateral dimension of the bottom portion is greater than a lateral dimension of the top portion, as illustrated. Moreover, the top portion is partially surrounded by the backside spacer layer 146, also as illustrated. Finally, a top of the bottom portion of each of the backside contact structures 154 is above a bottom of the placeholder 116.

After forming the backside contact structures 154, the backside wiring layers 156 are subsequently formed according to known techniques. The backside wiring layers 156 typically include at least backside power rails and a backside power delivery network.

With continued reference to FIGS. 32-34, and according to an embodiment, the structure 100 includes a placeholder directly beneath a source drain region, a backside contact structure adjacent to the placeholder, and a backside spacer layer surrounding the placeholder and partially surrounding a top portion of the backside contact structure.

With continued reference to FIGS. 32-34, and according to an embodiment, the backside spacer layer surrounds sides and a bottom of the placeholder.

With continued reference to FIGS. 32-34, and according to an embodiment, the backside spacer layer physically separates a backside dielectric layer from a gate.

With continued reference to FIGS. 32-34, and according to an embodiment, the backside spacer layer conformally contacts a top surface of a backside dielectric layer.

With continued reference to FIGS. 32-34, and according to an embodiment, vertical pillars of a backside dielectric layer are substantially aligned with inner spacers.

With continued reference to FIGS. 32-34, and according to an embodiment, the backside contact structure comprises a top portion having a first lateral dimension and a bottom portion having a second lateral dimension.

With continued reference to FIGS. 32-34, and according to an embodiment, a top of the bottom portion of the backside contact structure is above a bottom of the placeholder.

With continued reference to FIGS. 32-34, and according to an embodiment, the structure 100 includes a placeholder directly beneath a source drain region, a backside contact structure adjacent to the placeholder, and a backside spacer layer surrounding the placeholder and directly contacting bottommost surfaces of bottommost nanosheet channels.

With continued reference to FIGS. 32-34, and according to an embodiment, the structure 100 includes a placeholder directly beneath a source drain region, a backside contact structure adjacent to the placeholder, and a backside spacer layer surrounding the placeholder, where protruding portions of the backside dielectric are substantially aligned with nanosheet channels.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A nanosheet semiconductor structure comprising:
a placeholder directly beneath a source drain region;
a backside contact structure adjacent to the placeholder; and
a backside spacer layer surrounding the placeholder and partially surrounding a top portion of the backside contact structure.

2. The semiconductor structure according to claim 1, wherein the backside spacer layer surrounds sides and a bottom of the placeholder.

3. The semiconductor structure according to claim 1, wherein the backside spacer layer physically separates a backside dielectric layer from a gate.

4. The semiconductor structure according to claim 1, wherein the backside spacer layer conformally contacts a top surface of a backside dielectric layer.

5. The semiconductor structure according to claim 1, wherein vertical pillars of a backside dielectric layer are substantially aligned with inner spacers.

6. The semiconductor structure according to claim 1, wherein the backside contact structure comprises a top portion having a first lateral dimension and a bottom portion having a second lateral dimension.

7. The semiconductor structure according to claim 6, wherein a top of the bottom portion of the backside contact structure is above a bottom of the placeholder.

8. A nanosheet semiconductor structure comprising:
a placeholder directly beneath a source drain region;
a backside contact structure adjacent to the placeholder; and
a backside spacer layer surrounding the placeholder and directly contacting bottommost surfaces of bottommost nanosheet channels.

9. The semiconductor structure according to claim 8, wherein the backside spacer layer surrounds sides and a bottom of the placeholder.

10. The semiconductor structure according to claim 8, wherein the backside spacer layer physically separates a backside dielectric layer from a gate.

11. The semiconductor structure according to claim 8, wherein the backside spacer layer conformally contacts a top surface of a backside dielectric layer.

12. The semiconductor structure according to claim 8, wherein vertical pillars of a backside dielectric layer are substantially aligned with inner spacers.

13. The semiconductor structure according to claim 8, wherein the backside contact structure comprises a top portion having a first lateral dimension and a bottom portion having a second lateral dimension.

14. The semiconductor structure according to claim 13, wherein a top of the bottom portion of the backside contact structure is above a bottom of the placeholder.

15. A nanosheet semiconductor structure comprising:
a placeholder directly beneath a source drain region;
a backside contact structure adjacent to the placeholder; and
a backside spacer layer surrounding the placeholder, wherein protruding portions of the backside dielectric are substantially aligned with nanosheet channels.

16. The semiconductor structure according to claim 15, wherein the backside spacer layer physically separates a backside dielectric layer from a gate.

17. The semiconductor structure according to claim 15, wherein the backside spacer layer conformally contacts a top surface of a backside dielectric layer.

18. The semiconductor structure according to claim 15, wherein vertical pillars of a backside dielectric layer are substantially aligned with inner spacers.

19. The semiconductor structure according to claim 15, wherein the backside contact structure comprises a top portion having a first lateral dimension and a bottom portion having a second lateral dimension.

20. The semiconductor structure according to claim 19, wherein a top of the bottom portion of the backside contact structure is above a bottom of the placeholder.
